(19) United States
(12) Patent Application Publication
(10) Pub. No.: US 2020/0335940 A1
(43) Pub. Date: Oct. 22, 2020

(54) HIGH-ORDER BRAGG GRATING SINGLE-MODE LASER ARRAY

(71) Applicant: Hilux Optoelectron & Epiwafer Technology Inc., New York, NY (US)

(72) Inventor: Hai HUANG, Guangzhou (CN)

(21) Appl. No.: 16/398,202

(22) Filed: Apr. 29, 2019

(30) Foreign Application Priority Data
Apr. 22, 2019 (CN) 201910322200.1

(51) Int. Cl. H01S 5/12; H01S 5/026; H01S 5/22; H01S 5/042; H01S 5/40; H01S 5/028; H01S 5/022

(52) U.S. Cl. CPC H01S 5/1237; H01S 5/026; H01S 5/22; H01S 5/0224; H01S 5/4025; H01S 5/028; H01S 5/0425

(57) ABSTRACT

A high-order Bragg grating single-mode laser array. The laser array is capable of performing a variety of fixed channel spacings ranging from 25 GHz to 800 GHz. The laser array from bottom to top includes an active layer interposed between a first semiconductor confinement layer with the first conductivity type doping corresponding to the substrate, and a second semiconductor confinement layer with the second conductivity type doping corresponding to an Ohmic contact layer, an insulating film on the main surface side of the semiconductor substrate except for the upper surface of the ridge, and a second electrode which is disposed on the insulating film and contacts the Ohmic contact layer located upper the semiconductor confinement layer with the second conductivity type. The semiconductor laser array includes N semiconductor laser diodes, where N is an integer greater than one.

### CROSS-REFERENCE TO RELATED APPLICATIONS

Pursuant to 35 U.S.C. § 119 and the Paris Convention Treaty, this application claims foreign priority to Chinese Patent Application No. 201910322200.1 filed Apr. 22, 2019, the contents of which, including any intervening amendments thereto, are incorporated herein by reference. Inquiries from the public to applicants or assignees concerning this document or the related applications should be directed to: Matthias Scholl P. C., Attn.: Dr. Matthias Scholl Esq., 245 First Street, 18th Floor, Cambridge, Mass. 02142.

### BACKGROUND

This disclosure relates to optics and, more specifically, to optical interconnects and communication, as well as laser manufacturing, and particularly to a single-mode laser array and method of manufacturing the same.

The disclosure relates to a technology for manufacturing a high-order Bragg grating single-mode laser array capable of performing channel spacings ranging from 25 GHz to 800 GHz fabricated by standard lithography, for example, a technology effective for application to a technology for manufacturing a laser array capable of performing Dense Wavelength Division Multiplexing (DWDM) for optical communications.

In optical communication systems and networks, one of the most serious challenges is bandwidth bottlenecks in interchip interconnects, and a demand for DWDM has been made to transmission equipment with an increase in the amount of data to be transmitted. Optical interconnects are potential candidates for solving the bandwidth bottleneck.

The devices capable of realizing DWDM can be achieved in several of approaches. Current alternatives include Distributed Feedback (DFB) laser array and Vertical Cavity Surface Emitting Lasers (VCSELs) array, each possessing their own advantages and disadvantages for a particular system design. Several such prior art devices have different levels of reconfigurability and performance.

The regrowth process and high-resolution lithography techniques lead to high cost for the fabrication of DFB laser array. Low output power and weak lateral mode control ability restrict the application of VCSELs.

### SUMMARY

Disclosed is an improved method to realize a laser array capable of performing DWDM by using standard lithography. It is also one object of the disclosure to provide an improved and low-cost fabrication method for high-order Bragg grating single-mode laser array capable of performing a variety of fixed channel spacings ranging from 25 GHz to 100 GHz and wider (integer multiples of 100 GHz) as well as a flexible grid. Theoretically, one-order grating is low, and two and above order grating is high.

In the case of each high-order Bragg grating laser diode in the high-order Bragg grating single-mode laser array has a ridge structure, the first and second electrodes are disposed on the substrate and main surface of the semiconductor epiwafer to carry out the subsequent flip-chip heterointegration packaging, respectively.

The term “layer” does not exclude that the layer comprises two or more sublayers.

Disclosed is a laser array, comprising: N semiconductor laser diodes where N is an integer greater than one. The N semiconductor laser diodes comprise each:
a semiconductor substrate;
a first electrode disposed below the semiconductor substrate;
a first semiconductor confinement layer disposed on the semiconductor substrate and comprising a first conductivity type doping corresponding to the semiconductor substrate;
an active layer disposed on the first semiconductor confinement layer;
a second semiconductor confinement layer disposed on the active layer and comprising a second conductivity type doping;
a waveguide layer disposed on the second semiconductor confinement layer, the waveguide layer being in a ridge structure comprising a ridge and side faces, and the ridge comprising an upper surface;
an Ohmic contact layer disposed on the upper surface of the ridge, the Ohmic contact layer comprising an upper surface comprising a first region and a second region;
an insulating film disposed on the first region of the upper surface of the Ohmic contact layer and the side faces of the ridge structure of the waveguide layer; and
a second electrode disposed on the insulating film and the first region of the upper surface of the Ohmic contact layer.

The semiconductor substrate serves as an n-InP substrate, for example. An n-type lower Separate Confinement Heterostructure (SCH) formed of an AlGaInAs layer, an active layer made up of Multiple Quantum Wells (MQWs) or Quantum Dots (QDs) AlGaInAs layer, a p-type SCH and a p-type waveguide layer as well as an Ohmic contact layer are sequentially grown during epitaxy. An insulating film made up of silicon oxides and a metal layer are grown in succession. The metallized layer as the first electrode is grown on the back of the substrate.

Each high-order Bragg grating laser diode in the high-order Bragg grating laser array is a ridge microstructure and the ridge is formed at a portion interposed between the two trenches. The trenches are formed by standard lithography and etching technology. The p-type waveguide layer is exposed at the bottom of each trench. The ridge has a width of 3 μm and a length of 400 for example.

The high-order Bragg grating laser array comprises a first electrical contact, a substrate, a lower SCH, an active layer, a second SCH, a waveguide layer, an insulating film and a second electrical contact. An insulating film formed of a SiO₂ film; an anode electrode, which electrically contacts the Ohmic contact layer located upper the ridge; only the upper surface of the ridge is exposed without being covered with the insulating film. An anode electrode electrically contacts the Ohmic contact layer, a cathode electrode is provided on the back surface of the n-type substrate.

The active layer takes a MQWs or a QDs nanostructure. The active layer is AlGaInAs strained quantum wells or InAs/AlGaInAs quantum dots, for example.

According to high-order Bragg grating laser array fabricated by standard lithography, high-order gratings are provided on the surface of the ridge along the longitudinal direction of the ridge to configure a high-order Bragg grating structure. The multiple channels in the array are the parallel alignment of optical sources.

The disclosure improves upon alternative wavelength separation technology. The disclosure based on standard lithography allows multiple channels or wavelengths that are eligible for DWDM. Standard lithography adds tremendous flexibility to the realization of DWDM for optical communication and interconnects. According to the high-order Bragg grating laser array fabricated by standard lithography, the methods of changing the order of gratings, changing the pre-determined wavelength, or changing the order of gratings and the pre-determined wavelength simultaneously correspond to different channels in the laser array realize and enhance the yield of standard lithography for a variety of fixed channel spacings ranging from 25 GHz to 100 GHz and wider (integer multiples of 100 GHz) as well as a flexible grid. As means for fabrication of the laser array capable of performing DWDM networks based on standard lithography, there is (1) a method of changing etching width and grating period based on different pre-determined wavelengths and the same grating orders correspond to different channels or (2) a method of changing etching width and grating period based on different pre-determined wavelengths and different grating orders correspond to different channels.

Prefer 800 nm photoresist and stable room temperature condition produce high aspect ratio and fine linewidths features on photoresist. Precision-controlled lithography dose and developing time ensure the features on the lithography mask match the predetermined microstructures. Prefer 250 nm oxide as mask for dry etching of epiwafer. Yield degradation and the feature transfer deterioration are improved by reducing oxides thickness.

The high order Bragg gratings are formed on the surface of ridge along the longitudinal direction of the ridge to thereby configure a high-order Bragg grating laser diode. The etching width and the Bragg grating period depend on the effective refractive indices caused by the nanostructure of epiwafer and etching depth, the predetermined wavelengths, and the predetermined order of Bragg grating. The wavelength-selection is provided from the contributions of the reflectivity and the loss based on the Bragg's condition and the simulation of transfer matrix method.

The range of grating orders may preferably be between 5 and 50, more preferably between 15 and 40. The range of Bragg grating etching width may preferably be between 800 nm and 4 μm to satisfy the fabrication limitation for standard lithography and high aspect ratio etching technology.

The at least etching depth for high order grating on the ridge has a thickness between 1.1 μm and 1.5 μm. The etching depth can change the effective refractive indices of the output laser, and the prefer etching depth ensures that high reflection and small scattering loss are provided to realize stable single-mode lasing.

The range of the ridge width may be between 2 μm and 5 μm. The high-order mode is suppressed by the modification for etching depth and etching technique. Only the fundamental mode has priority over other modes for lasing due to a much larger gain for the fundamental mode under current injection. The largest etching depth of the ridge is 2 μm, more preferably between 1.4 μm and 1.8 μm to prevent etching through the active layer.

The etching width and period depend on the predetermined etching depth, pre-determined single-mode wavelength and order of Bragg grating. The wavelength-selection is realized based on the reflectivity and loss induced by the high-order Bragg grating microstructure.

The high-order Bragg grating laser array may comprise at least two laser diodes in the parallel alignment. Each laser diode has an individual single-mode wavelength lasing. Channel spacing is a variety of fixed channel spacings ranging from 25 GHz to 100 GHz and wider (integer multiples of 100 GHz) as well as a flexible grid. The output wavelengths satisfy the condition for DWDM networks.

All laser diodes are in parallel circuit and when a predetermined voltage or current is applied between the anode and the cathode, a total current are applied on the laser diodes in the laser array, different wavelengths single-mode laser light is emitted from the cleaved front surface of the active layer of the high-order Bragg grating laser array.

The high-order Bragg grating laser array built therein comprises a package having a plurality of external electrode terminals, and a support substrate.

The high-order Bragg grating laser array may preferably be manufactured according to the following method. The method comprises the steps of: multilayer semiconductor epiwafer growth, form ridge, form high-order Bragg grating microstructures, form insulating film, open ridge top and form contact holes, form electrode, polish back surface, form metallized layer, cleave the wafer into bars, divide the wafer into the bars. The method steps need not necessarily be performed in the order given above.

Specifically, the method comprises:
forming a ridge structure with several micrometer-level width, such as 2 μm to 5 μm, by standard lithography, such as i-line contact lithography, and inductively coupled plasma (ICP) dry etching;
forming high-order Bragg grating with micrometer-level or submicrometer-level microstructures by standard lithography, such as i-line contact lithography, and ICP dry etching. The high-order mode is suppressed by the design for etching depth and etching width, so only the fundamental mode has priority over other modes for lasing. The first output wavelength in the first channel, such as one wavelength satisfying the condition of telecommunication standardization sector of international telecommunication union, is proportional to etching width, such as micrometer-level or submicrometer-level width, the reciprocal of effective index of material, such as around 3, and the order of grating, such as 20. The output wavelengths have the same channel spacing with each other, such as 100 GHz.
forming an insulating film by the plasma enhanced chemical vapor deposition (PECVD) growth;
opening ridge windows under micrometer-level, such as 1 and forming contact holes by standard lithography, such as i-line contact lithography, and ICP dry etching;
forming an anode electrode, such as TiPtAu or TiAu, by sputtering or evaporation;
polishing a back surface with polished powders;
forming a metallized layer, such as AuGeNiAu or TiAu, by sputtering or evaporation; and
cleaving the wafer for bars, such as 400 μm long and 150 μm period.

Specifically, the method of fabrication of the laser array comprises:
defining the parameters of high order Bragg grating laser array, based on their reflection and losses of output wavelengths induced by the transfer matrix method and Bragg's law, pre-designed output wavelengths, and the nanostructure of epiwafers;
fabricating high order Bragg gratings as the defined microstructure parameters on the ridge structures by standard lithography and dry etching;
growing the insulating layer on the first region of the Ohmic contact layer and the side faces of the ridge;
fabricating the windows for electrical contact on the second region of the Ohmic contact layer;
disposing the first electrode below the substrate; and
disposing the second electrode on the second region of the Ohmic contact layer and the insulating layer.

The sequence of fabrication of ridge and high order Bragg gratings can be in an arbitrary order or simultaneously. The fabrication steps need not necessarily be performed in the order given above.

The disclosure in some embodiments provide the high-order Bragg grating laser array capable of performing DWDM networks fabricated by standard lithography. In certain embodiments, the high-order Bragg grating laser array apparatus comprises four laser diodes. The channel spacing in the array is designed as 100 GHz.

Upon performing DWDM, the reflection of high order Bragg grating for output wavelength is calculated based on the nanostructure of epiwafers and the etching depth; the first effective refractive index is calculated based on the nanostructure of epiwafer; the etching longitudinal width of high order Bragg grating can be obtained from the first effective index, the first pre-designed output wavelength, and the first pre-designed grating order based on Bragg's law; the second effective refractive index is calculated based on the nanostructure of epiwafer and the etching depth of the high order Bragg grating; the period of high order Bragg grating can be obtained from the second effective index, the first pre-designed output wavelength, and the second pre-designed grating order based on Bragg's law; and in the laser array capable of performing DWDM, the channel spacing between the second pre-designed output wavelength and the first pre-designed output wavelength satisfies the requirement of DWDM condition.

### BRIEF DESCRIPTION OF THE DRAWINGS

FIG. 1 is an enlarged three-dimensional view of the high-order Bragg grating laser array.

FIG. 2 is a two-dimensional top view of one embodiment of a high-order Bragg grating laser array.

FIG. 3 is a two-dimensional cross-sectional schematic view of the ridge from LINE 2 in the FIG. 2.

FIG. 4 is a two-dimensional cross-sectional schematic view of the ridge from LINE 1 in the FIG. 2.

FIG. 5 is a flowchart showing a manufacturing process of the semiconductor laser array of the first embodiment.

FIG. 6 is an enlarged three-dimensional view of the MQWs or QDs epiwafer.

FIG. 7 is an enlarged three-dimensional view of the ridge structure fabricated by standard lithography and dry etching.

FIG. 8 is an enlarged three-dimensional view of the high-order Bragg grating semiconductor laser array formed with etching high-order gratings on the ridge structures.

FIG. 9 is an enlarged three-dimensional view of the high-order Bragg grating semiconductor laser array upon manufacture of the semiconductor laser array of the first embodiment, the passivation film is selectively removed to form the contact windows for the electrode.

FIG. 10 is an enlarged three-dimensional view of the high-order Bragg grating semiconductor laser array formed with a surface anode electrode and a cathode electrode below the substrate upon manufacture of the semiconductor laser array of the first embodiment. The anode electrodes are separate coverings on the passivation film.

FIG. 11 is an optical spectrum of a four-channel semiconductor laser array fabricated based on i-line contact lithography of the first embodiment.

FIG. 12 is a PIV curves of a four-channel semiconductor laser array fabricated based on i-line contact lithography of the first embodiment.

FIG. 13 is an enlarged three-dimensional view of the high-order Bragg grating laser array formed with a surface anode electrode and a cathode electrode below the substrate upon manufacture of the high-order Bragg grating laser array of the second embodiment. The anode electrodes are the whole covering on the passivation film.

FIG. 14 is an enlarged three-dimensional view of the high-order Bragg grating laser array upon manufacture of the semiconductor laser array of the third embodiment, the laser diode in the array are separated by the unetched Ohmic and waveguide layers as well as the passivation film.

FIG. 15 is a two-dimensional cross-sectional schematic view of the laser array of the third embodiment.

FIG. 16 is an enlarged three-dimensional view of the high-order Bragg grating laser array upon manufacture of the high-order Bragg grating laser array of the fourth embodiment. The ridge structure and high-order Bragg gratings are formed for H-columns in the same step. The H-columns are made to provide fundamental mode selection and wavelength selection simultaneously.

FIG. 17 is a two-dimensional top schematic view of the H-columns in the fourth embodiment. The passivation film is selectively removed to form the contact windows for the electrode on the H-columns.

FIG. 18 is an enlarged three-dimensional view of the high-order Bragg grating laser array upon manufacture of the semiconductor laser array of the fifth embodiment. The anode electrodes are the whole covering on the passivation film.

FIG. 19 is an enlarged three-dimensional view of the high-order Bragg grating laser array upon manufacture of the semiconductor laser array of the sixth embodiment. The pits on the both sides of high-order gratings are formed due to low precision requirement for standard lithography, and thus simplifies fabrication technology.

FIG. 20 is an enlarged three-dimensional view of the high-order Bragg grating laser array upon manufacture of the semiconductor laser array of the seventh embodiment. The anode electrodes are the whole covering on the passivation film.

### DETAILED DESCRIPTION

Preferred embodiments of the disclosure will hereinafter be described in detail with reference to the accompanying drawings. Components each having the same function in all drawings for describing the embodiments of the disclosure are respectively identified by the same reference numerals and their repetitive description will be omitted.

### Example 1

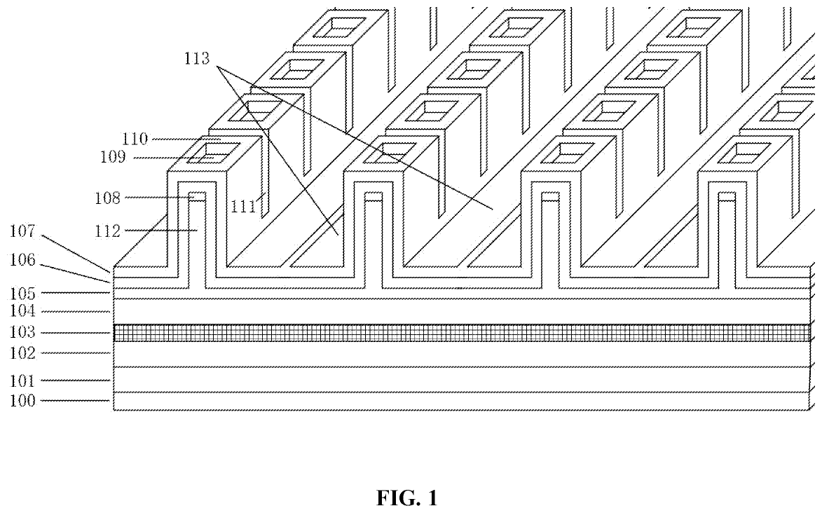

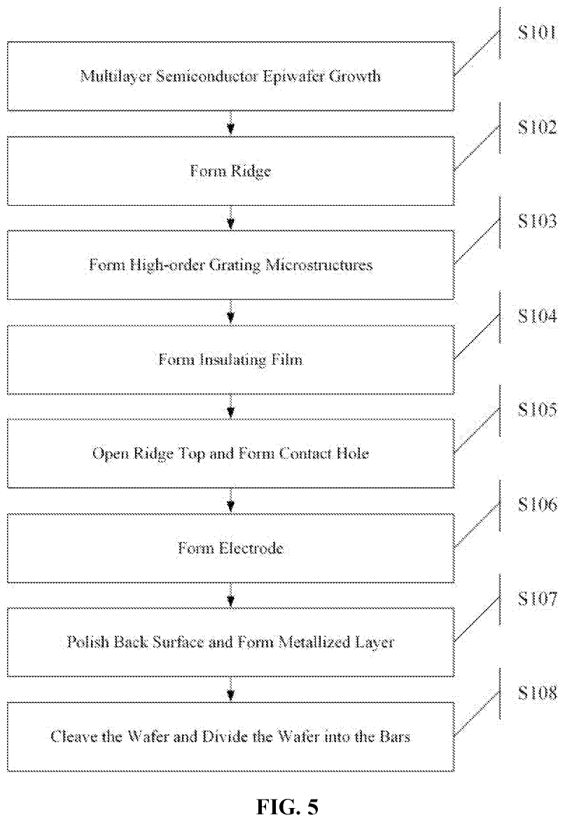

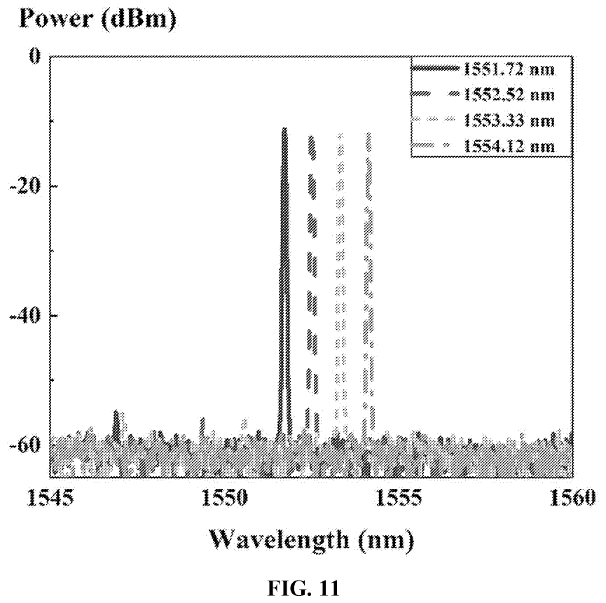

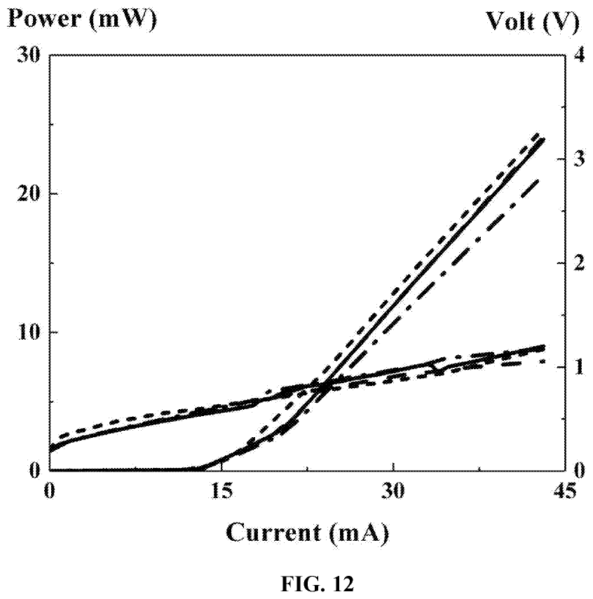

FIGS. 1 through 12 are diagrams related to a 100 GHz channel spacing high-order Bragg grating laser array fabricated by standard lithography, such as i-line contact lithography, showing the first embodiment of the disclosure. FIGS. 1 through 4 are diagrams related to the structure of the high-order Bragg grating laser array, FIG. 5 is a diagram related to a flowchart of manufacturing the high-order Bragg grating laser array, and FIGS. 6 through 10 are diagrams related to a method of manufacturing the semiconductor laser array, as well as FIGS. 11 and 12 are diagrams related to the device characteristics of the first embodiment of the disclosure.

As shown in FIGS. 1 through 4, the high-order Bragg grating laser array according to the first embodiment has a multilayered nanostructure comprising an active layer 103 on the main surface of a substrate 101, and is provided with an anode electrode 107 on the upper surface of the main surface and a cathode electrode 100 on the back surface of the substrate.

The anode electrode 107 and the cathode electrode 100 are provided on the both sides of the laser array. Both electrodes are satisfactory in wet characteristic with respect to a bonding material used upon fixing laser array to a mount, a heterointegratable Si-based substrate, or the like. Although not illustrated in the drawing, the forward output surface is coated with an anti-reflective film, whereas a backward surface is coated with another anti-reflective film.

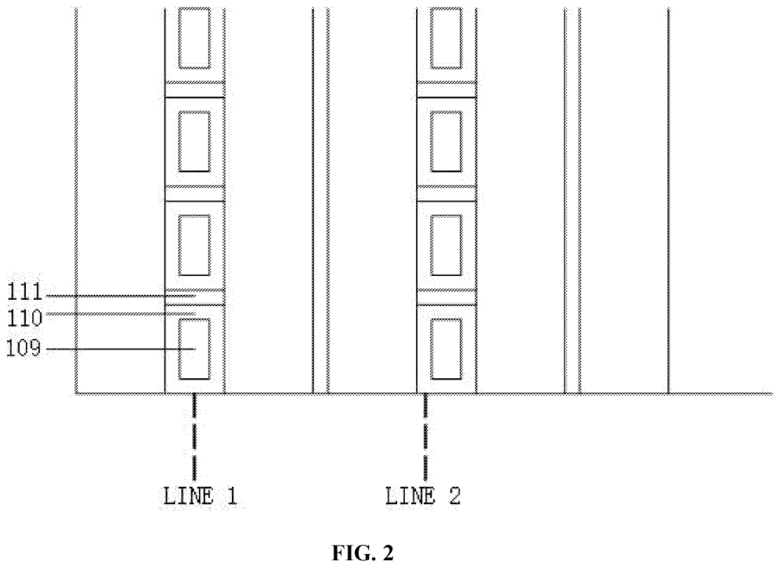

As shown in FIGS. 1 and 2, the substrate 101 serves as, for example, an n-InP substrate 101. An n-type lower SCH 102 made up of an n-AlGaInAs layer, an active layer 103 made up of MQWs or QDs AlGaInAs layer, a p-type SCH 104 and a p-type waveguide layer 105 as well as an Ohmic contact layer 108 are sequentially grown during epitaxy. An insulating film 106 made up of silicon oxides and an anode electrode 107 are grown in succession. The second electrode 100 is grown on the substrate 101. The active layer 103 serves as a MQWs nanostructure where a compressively strained AlGaInAs well layer and a lattice-matched AlGaInAs barrier layer are formed. For example, the well is 5 nm in thickness and the barrier is 10 nm in thickness.

The high-order Bragg grating laser diode in the laser array is a ridge structure and the ridge 112 is formed at a portion interposed between the two trenches 113. The trenches 113 are formed by etching the Ohmic contact layer 108 and p-type waveguide layer 105. The p-type waveguide layer 105 is exposed at the bottom of each trench 113. The ridge 112 has a width of 3 μm and a length of 400 μm, for example. The laser array has a width of 600 μm, a length of 400 μm and a thickness of 120 μm, for example.

As shown in FIGS. 1 through 4, an insulating film 106 is provided to cover the surface of the trench 113, (the side wall 109 of the ridge 112) and the first area of the upper surface 110 of the ridge. The insulating film is formed of an SiO₂ film, for example.

The anode electrode 107 is grown on the main surface of semiconductor laser array except for high-order Bragg gratings 111, and electrically contacts the Ohmic contact layer 108. The anode electrode is formed of TiPtAu or TiAu, for example.

The cathode electrode 100 is formed on the back of the substrate 101.

As shown in FIG. 2, the first area of the upper surface 110 of the ridge 112 is a rectangle region and the second area of the upper surface 109 of the ridge 112 is a smaller rectangle region in the first area of the upper surface 110. The high-order Bragg grating 111 is formed between two neighboring rectangle first areas of the upper surface 110 of the ridge 112.

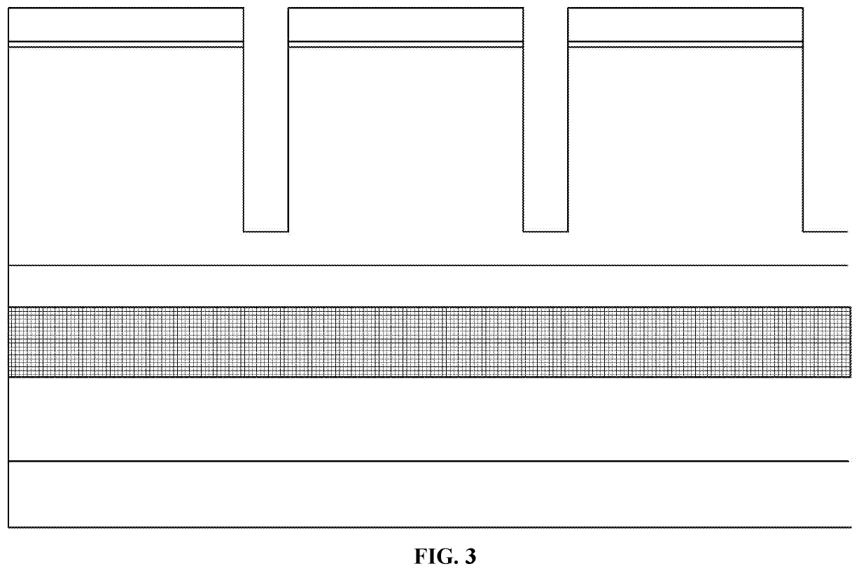

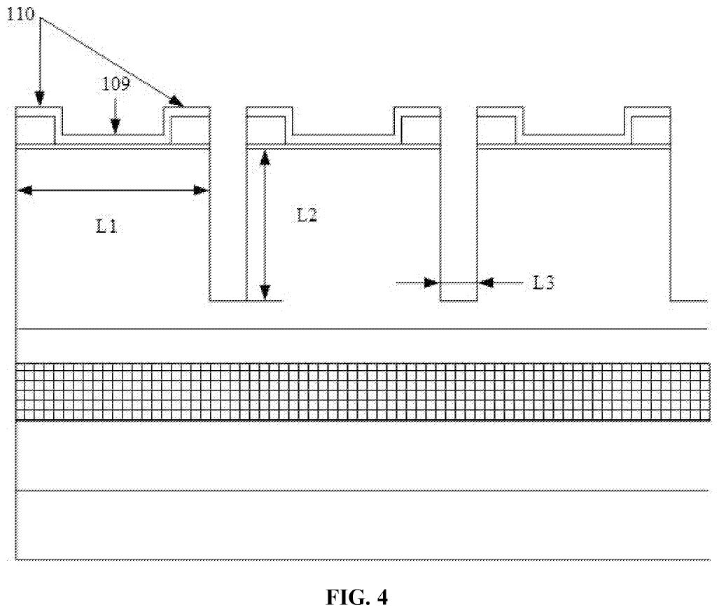

FIGS. 3 and 4 are two dimensional cross-sectional schematic views of the ridge from LINE 2 in the FIG. 2 and LINE 1 in the FIG. 2. The high-order Bragg grating 111 is formed by selectively dry etching on the ridge structure. The high order gratings 111 are formed on the surface of ridge along the longitudinal direction of the ridge to thereby configure a high-order Bragg grating laser. The etched width L3 and the unetched width L1 on the ridge 112 depend on the predetermined wavelengths based on the Bragg's condition and the effective refractive indices caused by the etching depth L2 and the effective refractive indices of epilayers. The order of grating in high-order Bragg grating laser diode is built in the range between 5 and 50. The etched width L3 is formed of around 0.901 μm and the unetched width L1 is formed of around 4.038 μm based on standard lithography, such as i-line contact lithography, for example. The etched depth is formed of around 1.65 μm, for example.

In the 100 GHz channel spacing high-order Bragg grating laser array, the predetermined channel spacing between two neighboring channels is 100 GHz. The etching depths for two neighboring channels are the same. The designed etched width L3 and the unetched width L1 in the second channel ensure the output wavelength has 100 GHz frequency grid spacing with the output wavelength from the first channel. The output wavelength is 1551.72 nm from the first channel, and the output wavelength is 1552.52 nm from the second channel, for example.

A method of manufacturing the high-order Bragg grating laser array according to the first embodiment is described with reference to FIGS. 5 through 10. In the first embodiment, a manufacturing method for forming a DWDM multiple-channel laser array fabricated by standard lithography, such as i-line contact lithography, is described.

As shown in a flowchart of FIG. 5, the DWDM multiple-channel laser array fabricated by standard lithography, such as i-line contact lithography, is manufactured as follows: multilayer semiconductor epiwafer growth (S101), form ridge (S102), form high-order Bragg gratings (S103), form insulating film (S104), open ridge top and form contact hole (S105), form electrode (S106), polish back surface and form metallized layer (S107), and cleave the wafer and divide the wafer into bars (S108).

As shown in FIG. 6, a strained MQWs AlGaInAs epiwafer is formed based on Metal Organic Chemical Vapor Deposition (MOCVD) apparatus.

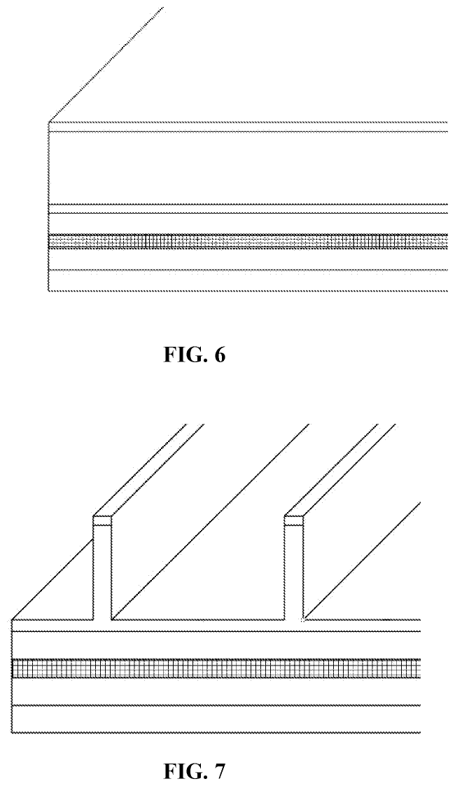

Next, as shown in FIG. 7, multi-ridge is defined in the main surface of the epiwafer in parallel by standard lithography technique, such as i-line contact lithography, and etching technology to form multi-channel array. Etching is performed so as to remove the Ohmic contact layer 108 and p-type waveguide layer 105.

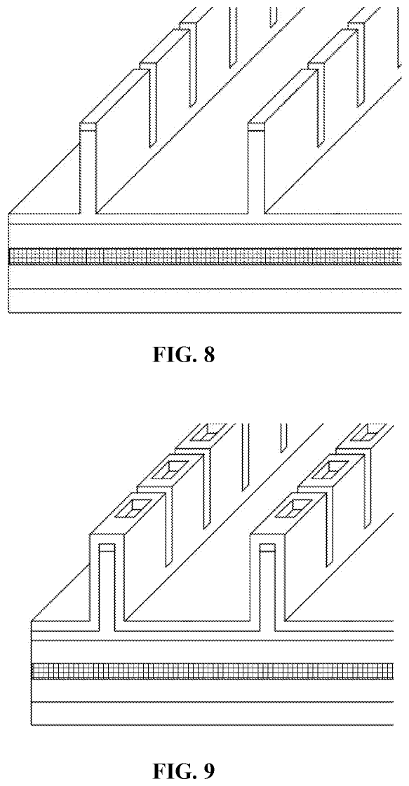

Next, as shown in FIG. 8, high-order Bragg gratings 111 are formed on the ridge 112 by standard lithography technique, such as i-line contact lithography, and etching technology. The predetermined wavelength-selection laser array structure is selectively formed on the ridge. The photoresist film is formed as an etching mask for oxides, and oxides is selectively formed as an etching mask for the epiwafer, for example.

Next, as shown in FIG. 9, an insulating film 106 made up of an SiO₂ film is formed over the whole main surface, except for the second area of the upper surface 109 of the ridge 112 in FIG. 2.

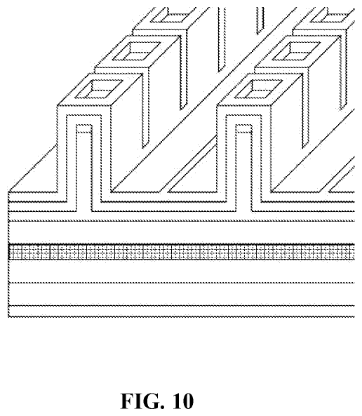

Next, as shown in FIG. 10, the anode electrode 107 is formed over the whole main surface, except for the high-order grating 111 in FIG. 2 and the interval between two channels. The cathode electrode 100 is formed on the back of the substrate 101 after polishing the back of the substrate 101 to take a predetermined thickness. The whole thickness of the epiwafer is set to, for example, about 120 μm. The epiwafer is sequentially divided by cleavage to form bars. The anti-reflective and reflective films are formed on the forward and backward surfaces, respectively.

The device characteristics of the high-order Bragg grating laser array fabricated based on i-line contact lithography according to the first embodiment are shown in FIGS. 11 through 12.

When a predetermined voltage or current is applied between the anode electrode 107 and the cathode electrode 100, the laser array emits laser from the surface of the active layer 103 corresponding to the ridge 112. Each channel corresponding to the ridge emits a single-mode laser from its active region. The laser diode in the array can be injected by the predetermined voltage or current individually or all diodes in the array can be injected by the predetermined voltage or current simultaneously. As shown in FIG. 11, the optical spectra from 4-channel 100 GHz channel spacing laser array fabricated based on i-line contact lithography are measured. As shown in FIG. 12, the power-current-voltage curves for 4-channel 100 GHz channel spacing laser array fabricated based on i-line contact lithography are measured. In the first embodiment, 40 dB SMSR or more is obtained under a CW condition.

According to the first embodiment, the following advantages are brought about. Since the laser array is fabricated by standard lithography, such as i-line contact lithography, the fabrication cost is reduced significantly, and the fabrication techniques are simplified. Since such a structure that the numbers of electrodes are small, the flip-chip packaging is made possible for integration with a mount, a heterointegratable Si-based substrate, or the like.

### Example 2

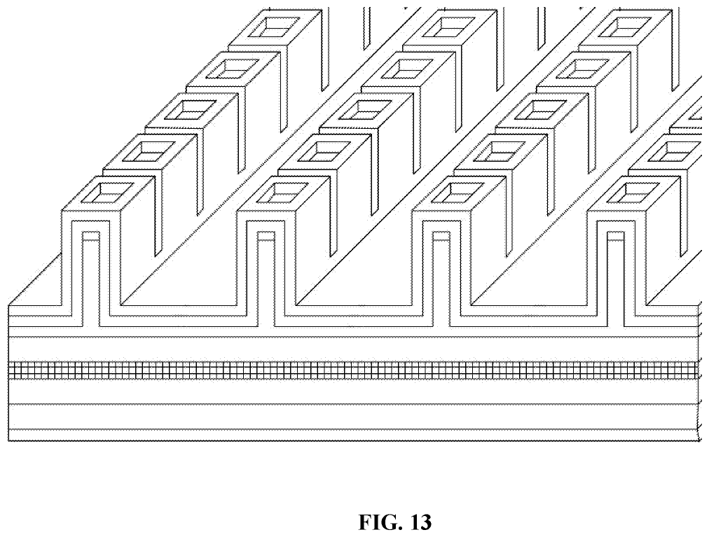

FIG. 13 is an enlarged three-dimensional view of the high-order Bragg grating laser array showing another embodiment (second embodiment) of the disclosure. Compared with the first embodiment, the anode electrodes are the whole covering on the passivation film, except for the high-order grating 111 in FIG. 2. The anode electrodes for all laser diode in the array are electrically connected.

### Example 3

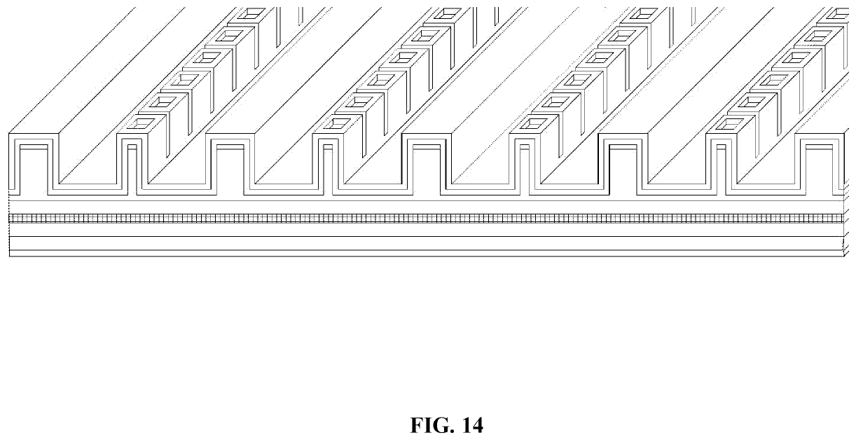

FIG. 14 is an enlarged three-dimensional view of the high-order Bragg grating laser array showing another embodiment (third embodiment) of the disclosure. Compared with the second embodiment, the laser diodes in the array are separated by the unetched Ohmic and waveguide layers as well as the passivation film. The third embodiment has a feature that the etching whole area except for ridge structure on the main surface as ridge fabrication becomes unnecessary. The feature is suitable for the manufacture of the laser array where the interval between two channels is wide.

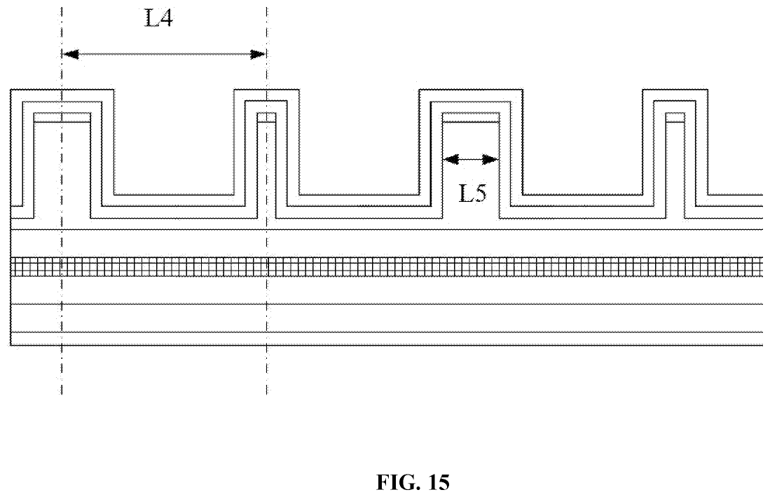

FIG. 15 is a two-dimensional cross-sectional schematic view of the laser array of the third embodiment. The unetched width L5 is formed of 70 μm and the half period L4 is formed of 50 for example.

### Example 4

FIG. 16 is an enlarged three-dimensional view of the high-order Bragg grating laser array showing another embodiment (fourth embodiment) of the disclosure. The fourth embodiment has a feature that the ridge structure and high-order Bragg gratings are formed for H-columns in the same step. The H-columns are made to provide fundamental mode selection and wavelength selection simultaneously. The anode electrodes are the whole covering on the passivation film, except for the high-order grating 111 in FIG. 2 and the interval between two neighboring channels.

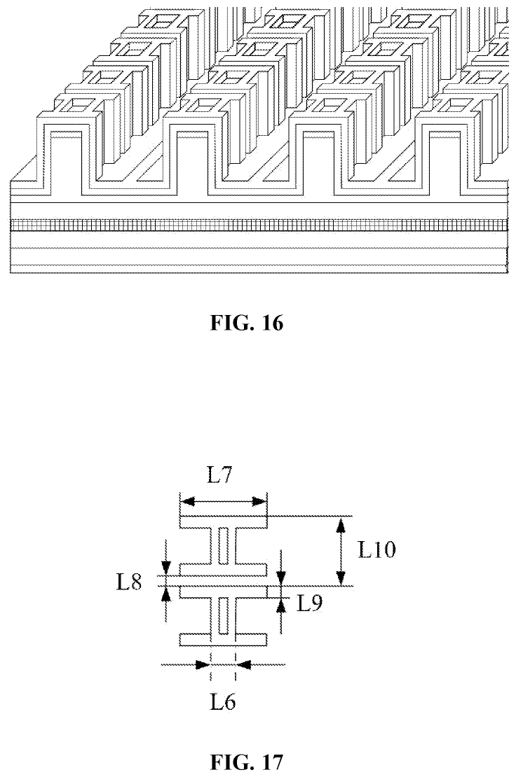

FIG. 17 is a two-dimensional top schematic view of the H-columns in the fourth embodiment. The passivation film is selectively removed to form the contact windows for the p-electrode on the H-columns. The ridge width L6 is formed of 3 the block width L7 is formed of 13 the high-order grating L8 is formed of around 0.901 the block longitudinal thickness L9 is formed of 1 and the period of grating L10 is formed of around 4.939 μm based on standard lithography, for example.

### Example 5

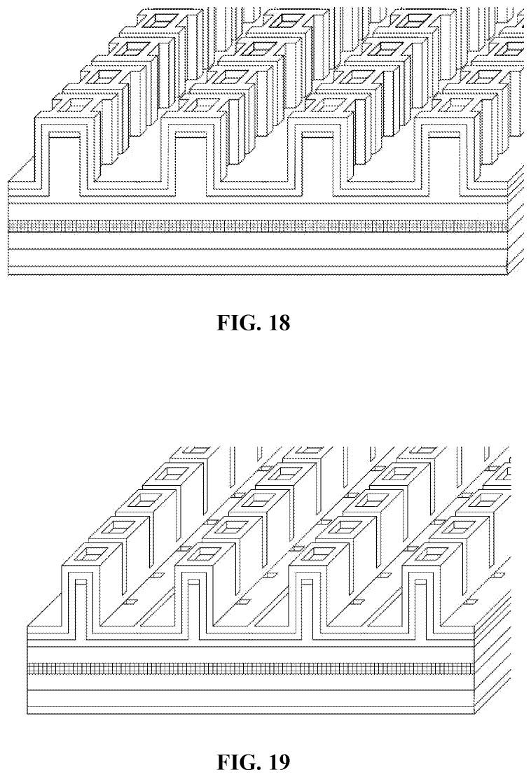

FIG. 18 is an enlarged three-dimensional view of the high-order Bragg grating laser array showing another embodiment (fifth embodiment) of the disclosure. Compared with the fourth embodiment, the anode electrodes are the whole covering on the passivation film, except for the high-order grating 111 in FIG. 2. The anode electrodes for all laser diode in the array are electrically connected.

### Example 6

FIG. 19 is an enlarged three-dimensional view of the high-order Bragg grating laser array showing another embodiment (Sixth embodiment) of the disclosure. The sixth embodiment has a feature that pits caused by low precision two-step lithography are etched through the active region. The anode electrodes are the whole covering on the passivation film, except for the high-order grating 111 in FIG. 2 and the interval between two neighboring channels.

The pits on the both sides of high-order gratings are formed due to low precision requirement for standard lithography, and thus simplifies fabrication technology.

### Example 7

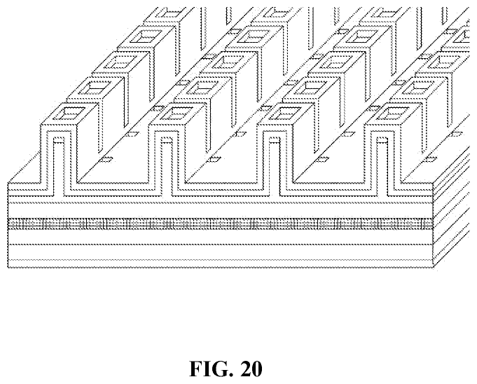

FIG. 20 is an enlarged three-dimensional view of the high-order Bragg grating laser array showing another embodiment (Seventh embodiment) of the disclosure. Compared with the sixth embodiment, the anode electrodes are the whole covering on the passivation film, except for the high-order grating 111 in FIG. 2. The anode electrodes for all laser diode in the array are electrically connected.

It will be obvious to those skilled in the art that changes and modifications may be made, and therefore, the aim in the appended claims is to cover all such changes and modifications.

What is claimed is:

1. A laser array, comprising: N semiconductor laser diodes, where N is an integer greater than one; wherein each of the N semiconductor laser diodes comprises:
a semiconductor substrate;
a first electrode disposed below the semiconductor substrate;
a first semiconductor confinement layer disposed on the semiconductor substrate and comprising a first conductivity type doping corresponding to the semi conductor substrate;
an active layer disposed on the first semiconductor confinement layer;
a second semiconductor confinement layer disposed on the active layer and comprising a second conductivity type doping;
a waveguide layer disposed on the second semiconductor confinement layer, the waveguide layer being in a ridge structure comprising a ridge and side faces, and the ridge comprising an upper surface;
an Ohmic contact layer disposed on the upper surface of the ridge, the Ohmic contact layer comprising an upper surface, the upper surface comprising a first region and a second region;
an insulating film disposed on the first region and the side faces; and
a second electrode disposed on the insulating film and the first region.

2. The laser array of claim 1, wherein each of the laser diodes in the laser array further comprises: two trenches disposed at two side of the ridge, respectively, M high order gratings on each ridge of the laser array where M is an integer greater than one, and each high order grating with a grating order of X where X is an integer greater than one.

3. The laser array of claim 1, wherein the laser array comprises fixed channel spacing ranging from 25 GHz to 800 GHz based on high-order gratings fabricated by standard lithography.

4. The laser array of claim 3, wherein the standard lithography comprises i-line contact lithography, waferstepper based lithography, and holographic exposure lithography.

5. The laser array of claim 1, wherein the laser diodes in the laser array further comprise two anti-reflection coatings or an anti-reflection coating and a reflection coating.

6. The laser array of claim 1, wherein the first and second electrodes of the laser array are packaged to predetermined wiring patterns by bonding or flip-chip package.

7. The laser array of claim 1, wherein a voltage or current is applied to the N semiconductor laser diodes, or Z laser diodes in the laser array individually or simultaneously where Z is an integer greater than zero.

8. The laser array of claim 1, further comprising a voltage control circuit situated to be in series with the laser array current to establish a laser array cathode voltage based on a selected laser array current.

9. A method of fabrication of the laser array of claim 1, the method comprising:
defining parameters of high order Bragg grating laser array, based on their reflection and losses of output wavelengths induced by a transfer matrix method and Bragg's law, pre-designed output wavelengths, and a nanostructure of epiwafers;
fabricating high order Bragg gratings as the defined parameters on ridge structures by standard lithography and dry etching;
growing an insulating layer on a first region of the Ohmic contact layer and the side faces of the ridge;
fabricating windows for electrical contact on the second region of the Ohmic contact layer;
disposing the first electrode below the substrate; and
disposing the second electrode on the second region of the Ohmic contact layer and the insulating layer.

10. The method of claim 9, wherein:
a reflection of the high order Bragg grating for output wavelength is calculated based on the nanostructure of epiwafers and an etching depth;
a first effective refractive index is calculated based on the nanostructure of epiwafer;
an etching longitudinal width of the high order Bragg grating is obtained from the first effective index, the first pre-designed output wavelength, and the first pre-designed grating order based on Bragg's law;
a second effective refractive index is calculated based on the nanostructure of epiwafer and the etching depth of the high order Bragg grating;
a period of the high order Bragg grating is obtained from the second effective index, the first pre-designed output wavelength, and the second pre-designed grating order based on Bragg's law; and
in the laser array capable of performing DWDM, the channel spacing between the second pre-designed output wavelength and the first pre-designed output wavelength satisfies the requirement of DWDM condition.

11. A method of fabrication of the laser array of claim 1, the method comprising:
forming a ridge structure with several micrometer-level width, by i-line contact lithography or inductively coupled plasma (ICP) dry etching;
forming high-order Bragg grating with micrometer-level or submicrometer-level microstructures by i-line contact lithography or ICP dry etching;
forming an insulating film by the plasma enhanced chemical vapor deposition (PECVD) growth;
opening ridge windows with micrometer-level and forming contact holes by i-line contact lithography or ICP dry etching;
forming an anode electrode by sputtering or evaporation;
polishing a back surface with polished powders;
forming a metallized layer by sputtering or evaporation; and
cleaving the wafer for bars.
